(19) United States
(12) Patent Application Publication
(10) Pub. No.: US 2023/0010602 A1
(43) Pub. Date: Jan. 12, 2023

(54) METHOD TO ENHANCE 3D VERTICAL DEVICE PERFORMANCE AND 3D CIRCUIT DENSITY

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(73) Assignee: Tokyo Electron Limited, Tokyo (JP)

(21) Appl. No.: 17/861,021

(22) Filed: Jul. 8, 2022

Related U.S. Application Data
(60) Provisional application No. 63/219,609, filed on Jul. 8, 2021.

(51) Int. Cl. H01L 29/423; H01L 29/786; H01L 29/06; H01L 29/45; H01L 27/088; H01L 21/822; H01L 21/8234

(52) U.S. Cl. CPC H01L 29/42392; H01L 29/78696; H01L 29/0673; H01L 29/456; H01L 27/088; H01L 21/8221; H01L 21/823475

(57) ABSTRACT

Semiconductor devices and corresponding methods of manufacture are disclosed. A method includes forming a stack of layers on a substrate. The stack includes a first sacrificial dielectric layer, a first metal layer, a second sacrificial dielectric layer, and a second metal layer vertically stacked on top of one another. The stack is etched to form a vertical opening. The opening is filled with a vertical structure. The vertical structure includes a first sacrificial semiconductor segment, a first semiconductor segment, a second sacrificial semiconductor segment, and a second semiconductor segment. The first and second sacrificial semiconductor segments are removed. Silicide layers are formed in the vertical structure to connect thereto.

### CROSS-REFERENCE TO RELATED APPLICATIONS

The present application claims the benefit of and priority to U.S. Provisional Patent Application No. 63/219,609, filed Jul. 8, 2021, and entitled “Method to Enhance 3D Vertical Device Performance and 3D Circuit Density,” the contents of which is incorporated by reference in its entirety for all purposes.

### FIELD OF THE DISCLOSURE

This disclosure relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

Techniques herein include methods of forming vertical transistors. Techniques herein enable an entire 3D cross section area of the source and drain regions of vertical channel transistors to be salicided prior to isolation. Enhanced conductivity and drive current (Idsat) is obtained because more surface area of the vertical cylinder is accessed. A robust circuit design of a dielectric stack and S/D access is provided that enables an entire stack of N devices to be salicided simultaneously. Embodiments can be used for any type of semiconductor material that utilizes salicidation. Methods herein are compatible with air gap device isolation (invention example shown) as well as dielectric device isolation (invention flow example shown). Accordingly, an efficient process flow is provided that greatly reduces process steps for both salicidation integrated with 3D isolation. Higher performance 3D transistors are obtained with such techniques.

In at least one aspect, the present solution relates to a transistor structure that can include, or be formed inside of, a stack of layers. The stack of layers can include a source contact layer and a gate contact layer with a first insulation layer between the gate contact layer and the source contact layer. The stack of layers can include a drain contact layer with a second insulation layer between the gate contact layer and the drain contact layer. The transistor structure can include a device region. The device region can be orthogonal to a plane defined by a surface of at least one of the layers in the stack of layers. The device region can include a source and drain separated by a channel region. The transistor structure can include silicide regions at ends of the device region proximal to the source and drain.

The transistor structure can include the gate contact layer that at least partially surrounds the channel region with a gate dielectric interposed between the gate contact layer and the channel region. The transistor structure can include the gate contact layer that forms a ring around the channel region with a gate dielectric interposed between the gate contact layer and the channel region. The transistor structure can include the device region that includes a dielectric surrounded by the source, drain, and channel.

The transistor structure can include a first silicide region at a first end of the device region in electrical contact with the source and a second silicide region at a second end of the device region in electrical contact with the drain. The transistor structure can include a hollow core extending orthogonally through a central portion of the device region, wherein the hollow core comprises air or dielectric material or a combination thereof. The transistor structure can include the source contact layer that is in electrical contact with the source via a first silicide region of the silicide regions and the drain contact layer is in electrical contact with the drain via a second silicide region of the silicide regions. The transistor structure can include the source, the gate and the drain that are vertically aligned and orthogonal to the plane.

In at least one aspect, the present solution relates to a gate all around (GAA) transistor structure that can include a substrate and a stack of layers upon the substrate. The stack of layers can include a source contact layer, a gate contact layer with a first insulation layer between the gate contact layer and the source contact layer, and a drain contact layer with a second insulation layer between the gate contact layer and the drain contact layer. The GAA transistor structure can include a device region orthogonal to a plane defined by a surface of at least one of the layers in the stack of layers. The device region can include a source and drain separated by a channel region that is at least partially surrounded by a gate dielectric interposed between the gate contact layer and the channel region. The GAA transistor structure can include a first region comprising a silicide formed at a first end of the device region proximal to the source and a second region comprising the silicide formed at a second end of the device region proximal to the drain.

The GAA transistor structure can include the device region that includes doped silicon and at least one of the first region and the second region includes silicide. The GAA transistor structure can include the source contact layer that is in electrical contact with the source via the first region and the drain contact layer is in electrical contact with the drain via the second region.

The GAA transistor structure can include the source, the gate and the drain that are vertically aligned and orthogonal to the plane. The GAA transistor structure can include a hollow core extending orthogonally through a central portion of the device region. The hollow core can include at least one of air or a dielectric material.

The source contact layer can be in electrical contact with the source via a first silicide region of the silicide regions and the drain contact layer is in electrical contact with the drain via a second silicide region of the silicide regions.

In some aspects, the present disclosure relates to a method that can include forming a stack of layers upon a substrate. The stack of layers can include a source contact layer, a gate contact layer with a first insulation layer between the gate contact layer and the source contact layer and a drain contact layer with a second insulation layer between the gate contact layer and the drain contact layer. The method can include forming a device region orthogonal to a plane defined by a surface of at least one of the layers in the stack of layers. The method can include forming a source of the device region. The method can include forming a drain of the device region. The method can include forming a channel region that is at least partially surrounded by a gate dielectric interposed between the gate contact layer and the channel region to form a gate of the device region. The channel region can separate the source from the drain. The method can include forming a first region comprising a silicide at a first end of the device region proximal to the source and a second region comprising the one of the silicide at a second end of the device region proximal to the drain.

The method can include forming a hollow core extending orthogonally through a central portion of the device region, wherein the hollow core comprises at least one of air or dielectric material. The method can include forming, by the gate contact layer, a ring around the channel region with the gate dielectric interposed between the gate contact layer and the channel region. The device region formed can include doped silicon and the first region can include silicide.

One aspect of the present disclosure may be directed to a semiconductor device. The semiconductor may include a vertical structure. The vertical structure may include a first semiconductor segment; a first silicide layer in contact with a bottom surface of the first semiconductor segment; a second silicide layer in contact with a top surface of the first semiconductor segment; a second semiconductor segment vertically spaced from the first semiconductor segment; a third silicide layer in contact with a bottom surface of the second semiconductor segment; and a fourth silicide layer in contact with a top surface of the second semiconductor segment.

The vertical structure of the semiconductor device may include a first high-k dielectric layer around a sidewall of the first semiconductor segment; and a second high-k dielectric layer around a sidewall of the second semiconductor segment.

The semiconductor device may include a first interconnect structure in electrical contact with the first silicide layer; a second interconnect structure in electrical contact with the first semiconductor segment; a third interconnect structure in electrical contact with the second silicide layer; a fourth interconnect structure in electrical contact with the third silicide layer; a fifth interconnect structure in electrical contact with the second semiconductor segment; and a sixth interconnect structure in electrical contact with the fourth silicide layer.

Each of the third to the sixth interconnect structures of the semiconductor device may include a lateral portion and a vertical portion.

The lateral portion of each of the first to sixth interconnect structures of the semiconductor device may be in physical contact with a corresponding one of the first silicide layer, the first semiconductor segment, the second silicide layer, the third silicide layer, the second semiconductor segment, or the fourth silicide layer.

The respective vertical portions of the first to sixth interconnect structures of the semiconductor device may be arranged in parallel with one another.

The first semiconductor segment of the semiconductor device may include a first conductive type; the second semiconductor segment of the semiconductor device may include a second conductive type opposite to the first conductive type.

The vertical structures of the semiconductor device can include at least one air gap between the second silicide layer and the third silicide layer.

The vertical structure of the semiconductor device can include a dielectric segment in direct contact with both of the second silicide layer and the third silicide layer. The semiconductor device may include a second vertical structure laterally spaced from the vertical structure including a third semiconductor segment; a fifth silicide layer in contact with a bottom surface of the third semiconductor segment; a sixth silicide layer in contact with a top surface of the third semiconductor segment; a fourth semiconductor segment vertically spaced from the third semiconductor segment; a seventh silicide layer in contact with a bottom surface of the fourth semiconductor segment; and an eighth silicide layer in contact with a top surface of the fourth semiconductor segment.

Another aspect of the present disclosure may be directed to a semiconductor device. The semiconductor device may include a first vertical structure and a second vertical structure. The first vertical structure may include a first silicide layer in contact with a bottom surface of the first semiconductor segment; a second silicide layer in contact with a top surface of the first semiconductor segment; a second semiconductor segment vertically spaced from the first semiconductor segment; a third silicide layer in contact with a bottom surface of the second semiconductor segment; and a fourth silicide layer in contact with a top surface of the second semiconductor segment. The second vertical structure may be laterally spaced from the first vertical structure. The second vertical structure may include a third semiconductor segment; a fifth silicide layer in contact with a bottom surface of the third semiconductor segment; a sixth silicide layer in contact with a top surface of the third semiconductor segment; a fourth semiconductor segment vertically spaced from the third semiconductor segment; a seventh silicide layer in contact with a bottom surface of the fourth semiconductor segment; and an eighth silicide layer in contact with a top surface of the fourth semiconductor segment.

The first semiconductor segment and the third semiconductor segment of the semiconductor device may be laterally aligned with each other. The second semiconductor segment and the fourth semiconductor segment of the semiconductor device may be laterally aligned with each other.

The first semiconductor segment and the third semiconductor segment of the semiconductor device may include a first conductive type. The second semiconductor segment and the fourth semiconductor segment of the semiconductor device may include a second conductive type.

The semiconductor device may include a first interconnect structure in electrical contact with the first silicide layer; a second interconnect structure in electrical contact with the first semiconductor segment; a third interconnect structure in electrical contact with the second silicide layer; a fourth interconnect structure in electrical contact with the third silicide layer; a fifth interconnect structure in electrical contact with the second semiconductor segment; a sixth interconnect structure in electrical contact with the fourth silicide layer; a seventh interconnect structure in electrical contact with the fifth silicide layer; an eighth interconnect structure in electrical contact with the third semiconductor segment; a ninth interconnect structure in electrical contact with the sixth silicide layer; a tenth interconnect structure in electrical contact with the seventh silicide layer; an eleventh interconnect structure in electrical contact with the fourth semiconductor segment; a twelfth interconnect structure in electrical contact with the eighth silicide layer.

The first to third interconnect structures of the semiconductor device may be disposed on a first side of the first vertical structure. The fourth to sixth interconnect structures of the semiconductor device may be disposed on a second, opposite side of the first vertical structure. The seventh to ninth interconnect structures of the semiconductor device may be disposed on a first side of the second vertical structure. The tenth to twelfth interconnect structures of the semiconductor device may be disposed on a second, opposite side of the second vertical structure.

Each of the first to twelfth interconnect structures of the semiconductor device may have a lateral portion and a vertical portion.

The first vertical structure of the semiconductor device may include at least one first air gap between the second silicide layer and the third silicide layer. The second vertical structure of the semiconductor device may include at least one second air gap between the sixth silicide layer and the seventh silicide layer.

Another aspect of the present disclosure may be directed to a method for manufacturing a semiconductor device. The method may include forming a stack of layers on a substrate, wherein the stack includes a first sacrificial dielectric layer, a first metal layer, a second sacrificial dielectric layer, and a second metal layer vertically stacked on top of one another; etching the stack to form a vertical opening; filling the vertical opening with a vertical structure, wherein the vertical structure includes a first sacrificial semiconductor segment, a first semiconductor segment, a second sacrificial semiconductor segment, and a second semiconductor segment; removing the first sacrificial semiconductor segment and the second first sacrificial semiconductor segment, while leaving the first semiconductor segment and the second first semiconductor segment substantially intact; and forming, in the vertical structure, a first silicide layer, a second silicide layer, a third silicide layer, and a fourth silicide layer in contact with a bottom surface of the first semiconductor segment, a top surface of the first semiconductor segment, a bottom surface of the second semiconductor segment, and a top surface of the second semiconductor segment, respectively.

The method can include forming a first interconnect structure including a lateral portion and a vertical portion, the lateral portion of the first interconnect structure being in electrical contact with the first silicide layer; forming a second interconnect structure including the first metal layer and a vertical portion, the first metal layer being in electrical contact with the first semiconductor segment; forming a third interconnect structure including a lateral portion and a vertical portion, the lateral portion of the third interconnect structure being in electrical contact with the second silicide layer; forming a fourth interconnect structure including a lateral portion and a vertical portion, the lateral portion of the fourth interconnect structure being in electrical contact with the third silicide layer; forming a fifth interconnect structure including the second metal layer and a vertical portion, the second metal layer being in electrical contact with the second semiconductor segment; and forming a sixth interconnect structure including a lateral portion and a vertical portion, the lateral portion of the sixth interconnect structure being in electrical contact with the fourth silicide layer.

The first semiconductor segment and the second semiconductor segment may each be formed of silicon. The first sacrificial semiconductor segment and the second sacrificial semiconductor segment may each be formed of silicon germanium. The first semiconductor segment may include a first conductive type, the second semiconductor segment may include a second conductive type.

3D integration, e.g., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

Techniques herein include methods of forming vertical transistors. Techniques herein enable an entire 3D cross section area of the source and drain regions of vertical channel transistors to be salicided prior to isolation. Enhanced conductivity and drive current (Idsat) is obtained because more surface area of the vertical cylinder is accessed. A robust circuit design of a dielectric stack and source/drain access is provided such that a plurality of stacked devices can be salicided simultaneously. Embodiments can be used for any type of semiconductor material that utilizes salicidation. Methods herein are compatible with air gap device isolation as well as dielectric device isolation. Accordingly, an efficient process flow is provided having a reduced set of process steps for both salicidation integrated with 3D isolation, relative to at least some embodiments. High performance 3D transistors can be obtained with such techniques.

Techniques herein relate to vertical channel transistors in which a current flow path of a transistor channel is perpendicular or vertical to a working surface of a wafer. Techniques herein include silicide formation by using a separate dielectric layer. This includes silicide formation after etching (e.g., with a silicon-germanium sacrificial layer) using a separate dielectric through a trench hole or other opening.

For example, two different type transistors (e.g., n-type and p-type) can be formed as a structure with one transistor stacked on top of another. The transistor pair can be a complementary field-effect-transistor structure. For example, one or more connections of the transistor pair can be silicided, e.g., to lower an electrode resistance, and can function as portion of a larger circuit. For example, the transistors may be matched (e.g., can include similar process variations) and self-aligned such that the transistors can form an a matched pair, which can be included in larger circuits, or can be used independently. In some embodiments, additional stacked transistor (e.g., paired transistors or non-paired transistors) can be formed. For example, stacks of three, four, five, or more vertical transistors can be formed according to some embodiments.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise. References to “or” may be construed as inclusive so that any terms described using “or” may indicate any of a single, more than one, and all of the described terms.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a flow chart of a method for making a semiconductor device, in accordance with some embodiments.

FIGS. 2A and 2B illustrate a top view and a cross sectional view of a semiconductor device, respectively, during various fabrication stages, made by the method of FIG. 1, in accordance with some embodiments.

FIGS. 3A and 3B illustrate a top view and a cross-sectional view of a semiconductor device, respectively, during various fabrication stages, made by the method of FIG. 1, in accordance with some embodiments.

FIGS. 4A and 4B illustrate a top view and a cross-sectional view of a semiconductor device, respectively, during various fabrication stages, made by the method of FIG. 1, in accordance with some embodiments.

FIGS. 5A and 5B illustrate a top view and a cross-sectional view of a semiconductor device, respectively, during various fabrication stages, made by the method of FIG. 1, in accordance with some embodiments.

FIGS. 6A and 6B illustrate a top view and a cross-sectional view of a semiconductor device, respectively, during various fabrication stages, made by the method of FIG. 1, in accordance with some embodiments.

FIGS. 7A and 7B illustrate a top view and a cross-sectional view of a semiconductor device, respectively, during various fabrication stages, made by the method of FIG. 1, in accordance with some embodiments.

FIGS. 8A and 8B illustrate a top view and a cross-sectional view of a semiconductor device, respectively, during various fabrication stages, made by the method of FIG. 1, in accordance with some embodiments.

FIGS. 9A and 9B illustrate a top view and a cross-sectional view of a semiconductor device, respectively, during various fabrication stages, made by the method of FIG. 1, in accordance with some embodiments.

FIGS. 10A and 10B illustrate a top view and a cross-sectional view of a semiconductor device, respectively, during various fabrication stages, made by the method of FIG. 1, in accordance with some embodiments.

FIGS. 11A and 11B illustrate a top view and a cross-sectional view of a semiconductor device, respectively, during various fabrication stages, made by the method of FIG. 1, in accordance with some embodiments.

FIG. 12 is another flow chart of a method for making a semiconductor device, in accordance with some embodiments.

FIGS. 13A and 13B illustrate a top view and a cross-sectional view of a semiconductor device, respectively, during various fabrication stages, made by the method of FIG. 12, in accordance with some embodiments.

FIG. 14 is another flow chart of a method for making a semiconductor device, in accordance with some embodiments.

FIGS. 15A and 15B illustrate a top view and a cross-sectional view of a semiconductor device, respectively, during various fabrication stages, made by the method of FIG. 14, in accordance with some embodiments.

FIGS. 16A and 16B illustrate a top view and a cross-sectional view of a semiconductor device, respectively, during various fabrication stages, made by the method of FIG. 14, in accordance with some embodiments.

FIGS. 17A and 17B illustrate a top view and a cross-sectional view of a semiconductor device, respectively, during various fabrication stages, made by the method of FIG. 14, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Disclosed herein are embodiments related to one or more vertical transistor structures having one or more silicide layers. In some embodiments, the silicide layers are in contact with a top and bottom surface of one or more semiconductor segments (e.g., transistor bodies) of said vertical transistor structures. Based on such silicide layers, advantageously, the vertical transistor structures, as disclosed herein, may include low impedance connections between interconnect structures for the various electrodes of the vertical transistor structures. In some aspects, any number of the vertical transistor structures can be laterally (e.g., side-by-side) arranged with each other and vertically stacked on top of one another, thereby forming an array of vertical transistor structures having improved characteristics in an area efficient manner. For example, with two different conductive types of the disclosed transistor structure stacked on top of one another, a complementary field-effect-transistor structure can be formed. In one aspect, the silicide or other layers formed on the sidewalls of the semiconductor segments can mechanically support the semiconductor segments. For example, air gaps can be formed and optionally filled with a dielectric at least above and below the semiconductor segments to reduce a capacitance between various conductive elements of a semiconductor device including the vertical transistor structures.

Reference will now be made to the figures, which for the convenience of visualizing the 3D fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a circular configuration, other shapes are also contemplated, and indeed the techniques described herein may be implemented in any shape or geometry.

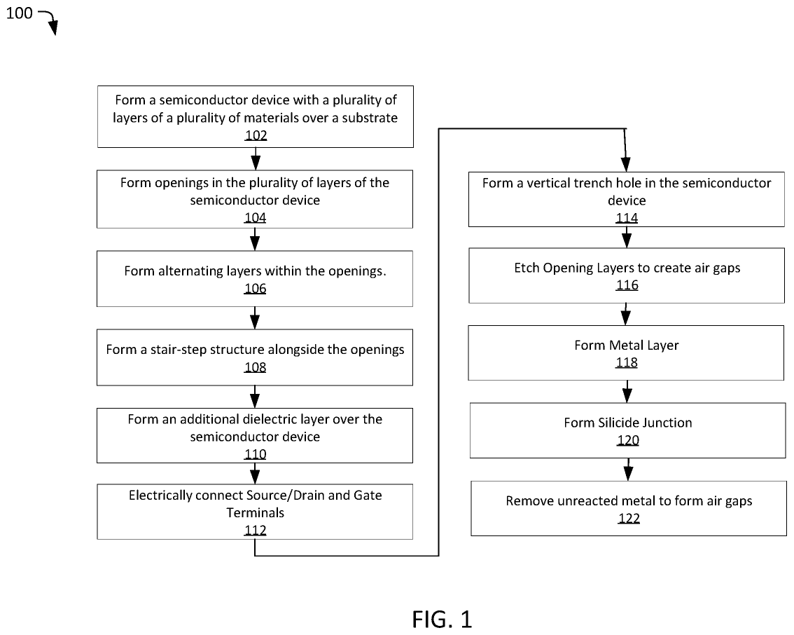

FIG. 1 illustrates a flowchart of an example method 100 for forming a semiconductor device (e.g., one or more transistors) based on a vertical stack structure. For example, the one or more transistors may be vertical stacked transistors with a silicided portion (e.g., a plurality of silicide layers) electrically connecting one or more electrodes to the body of at least one vertically stacked transistor, which is also referred to herein as a semiconductor segment. It is noted that the method 100 is merely an example, and is not intended to limit the present disclosure. Accordingly, it is understood that additional operations may be provided before, during, and after the method 100 of FIG. 1, and that some other operations may only be briefly described herein.

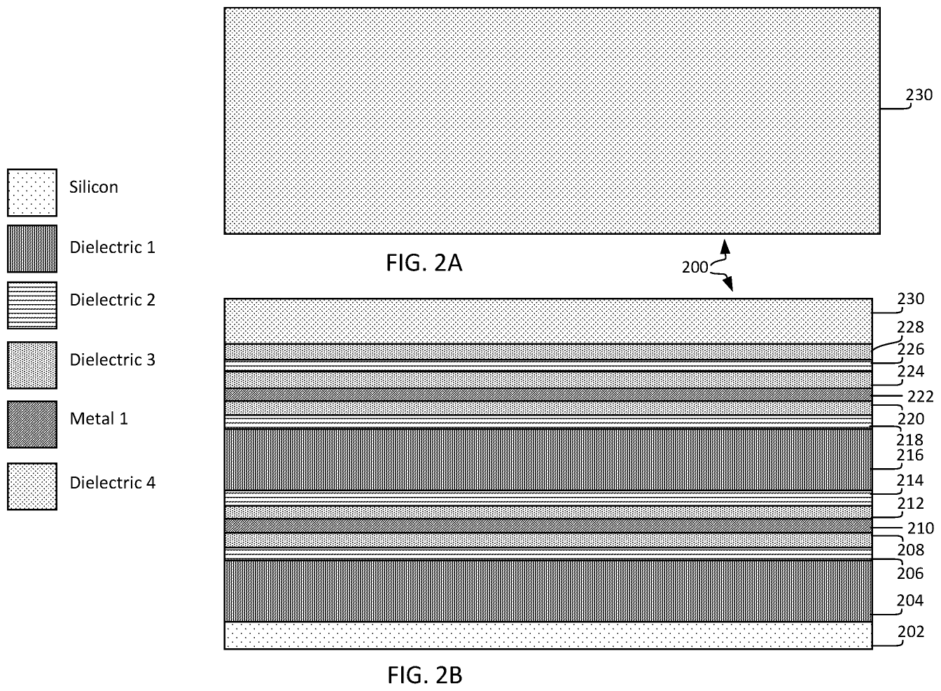

In various embodiments, operations of the method 100 may be associated with top views and cross-sectional views of an example semiconductor device 200 at various fabrication stages as shown in FIGS. 2A to 11A and FIGS. 2B to 11B, respectively, which will be discussed in further detail below. It should be understood that the semiconductor device 200, shown in FIGS. FIGS. 2A to 11A and FIGS. 2B to 11B, may include a number of other devices such as inductors, fuses, capacitors, coils, etc., while remaining within the scope of the present disclosure.

In brief overview, the method 100 starts with operation 102 of forming a semiconductor device comprising a plurality of materials formed over a substrate. The method 100 continues to operation 104 of forming a number of openings in the semiconductor device. In various embodiments, the openings can be generally cylindrical. The method 100 proceeds to operation 106 of forming a plurality of layers disposed within the openings of the semiconductor device. The method 100 proceeds to operation 108 of forming a vertical portion of an interconnect structure alongside the openings. In some embodiments, the interconnect structure can be or include a stair-step structure. The method 100 proceeds to operation 110 of forming an additional dielectric layer over the semiconductor device. The method 100 proceeds to operation 112 of electrically connecting the lateral portion of the interconnect structures to the vertical portion of the interconnect structures (e.g., the source/drain and gate terminals). The method 100 proceeds to operation 114 of forming a vertical trench in the semiconductor device. The method 100 proceeds to operation 116 whereby one or more opening layers are etched to create air gaps. The method 100 proceeds to operation 118 of forming a metal layer over the semiconductor device. The method 100 proceeds to operation 120 of forming a silicide junction. The method 100 proceeds to operation 122 of removing unreacted metal to form one or more air gaps.

Corresponding to operation 102 of FIG. 1, FIG. 2A is a top view of the semiconductor device 200 in which a plurality of layers (e.g., blanket layers), including a plurality of materials (e.g., conductive and dielectric materials), are formed over a substrate 202 (e.g., a crystalline silicon, a glass substrate, etc.). FIG. 2B is a corresponding cross-sectional view of the semiconductor device 200, in accordance with various embodiments.

As shown in FIG. 2B, a first layer 204 of a first dielectric material can be formed over the substrate 202. For example, the first layer 204 and the various additional dielectric and conductive layers and materials herein can be placed, grown, (e.g., epitaxially with or without a seed layer), or otherwise formed to create layers of the semiconductor device 200. The formation of the various layers of the semiconductor device 200 can include planarization of the layers, such as by cutting, ablation, chemical mechanical grinding or polishing (CMG/P), or other planarization techniques. A second layer 206 or a second dielectric material is formed over the first layer 204. The second layer 206 can include a different dielectric material than the first dielectric material. For example, the different dielectric material can be configured to be selectively etch-able or diffusible, relative to one or more adjacent layers (e.g., the first layer 204 and a third layer 208, formed overt the second layer 206). In some embodiments, the second layer 206 can be configured for conduction (e.g., to form a conductive element to connect to a source or drain of a vertical transistor). The conductive material, such as a heavily doped dielectric material can be configured to be or connect to the drain or source electrode of a vertical transistor, or the selective etch-ability of the second layer 206 can aid a subsequent removal and replacement with all or a portion of the second layer 206 with a conductive material. A third layer 208 can be formed over the second layer 206 of the semiconductor device 200. The third layer 208 can include a third dielectric material. For example, the third layer 208 can be or include a second dielectric material which is different from the first dielectric material or the second dielectric material, such as a sacrificial dielectric layer configured to be horizontally etched.

A fourth layer 210 can be formed over the third layer 208 of the semiconductor device 200. The fourth layer 210 can be a conductive layer. For example, the fourth layer 210 can be a highly doped semiconductor (e.g., silicon) or a metal layer configured to form the gate electrode of one or more transistors. The conductive material, such as the metal. A fifth layer 212 can be formed over the fourth layer 210. The fifth layer 212 can be a dielectric (e.g., can be the third dielectric material, such that each drain/source of a transistor is isolated from the gate or the gate electrode). A sixth layer 214 can be formed over the fifth layer 212. The sixth layer 214 can be a dielectric configured to be conductive or to be replaced with a conductive material (e.g., by selective horizontal etching). The sixth layer 214 can be or include the drain/source or drain/source electrode (e.g., upon replacement with a conductive material). For example, the sixth layer 214 can be formed from the second dielectric material. A seventh layer 216 includes a dielectric. For example, the seventh layer 216 can include a dielectric which can be selectively etch-able relative to the sixth layer 214 and an eighth layer 218. The eighth layer 218 can be or include a dielectric material which can be configured to electrically connect to the drain/source of a second transistor such as by replacement or a diffusion process to render the eighth layer 218 conductive. For example, the eighth layer 218 can be a same second dielectric material as the second layer 206, or the sixth layer 214. Similarly, the ninth layer 220, tenth layer 222, eleventh layer 224, and twelfth layer 226 may be similar to the third layer 208, fourth layer 210, fifth layer 212, and sixth layer 214, respectively. In some embodiments, one or more of the ninth layer 220, tenth layer 222, eleventh layer 224, or twelfth layer 226 can be a different material or a different dimension than the respective third layer 208, fourth layer 210, fifth layer 212, or sixth layer 214. For example, an upper transistor and lower transistor formed therefrom can be of differing construction (e.g., to form a complementary pair of transistors). For example, an n-type transistor can be of a smaller dimension that a p-type complimentary transistor (e.g., to form two transistors having similar total electron mobility or other performance characteristics).

A thirteenth layer 228 can be formed over the twelfth layer 226. For example, the thirteenth layer 228 can be or include a dielectric material which is compatible with a dielectric cap layer. The fourteenth layer 230 can be a dielectric cap layer to form an upper surface of the semiconductor device 200. The fourteenth layer 230 is depicted in the top view of FIG. 2A. In some embodiments, the eleventh layer 224 can be or can interface with a selected cap layer, and the twelfth layer 226 or thirteenth layer 228 may be omitted. In some embodiments, various interstitial layers or sublayers can be included. The various dielectric and conductive materials can vary, such as according to an interface with additional materials or an additive or subtractive process (e.g., various etches or resists). For example, in some embodiments, each layer described herein can be formed from a different material. In some embodiments, a plurality of the layers depicted herein can be similar. For example, a first dielectric material can form each dielectric layer, and a first conductive material can form each conductive layer (e.g., gate/drain/source electrodes). Some embodiments can include additional layers to form additional transistors. For example, a set comprising the first layer 204 through the sixth layer 214 can be repeatedly formed three, four, or five times to form three, four, or five vertically stacked transistors.

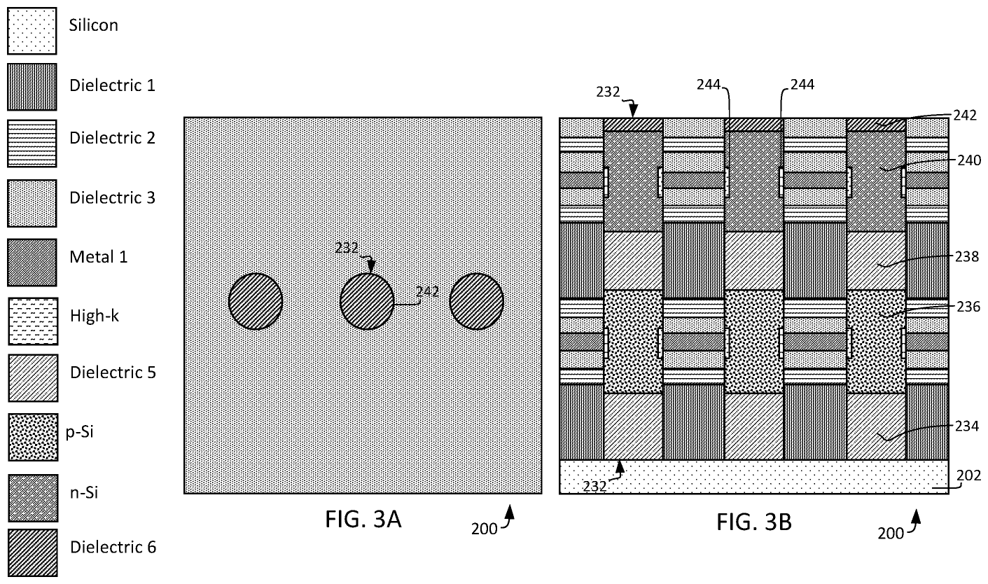

Corresponding to operations 104 and 106 of FIG. 1, FIG. 3A is a top view of the semiconductor device 200 in which a plurality of openings 232 are formed in the semiconductor device 200 (e.g., at operation 104), and a plurality of layers are formed therein (e.g., at operation 106). FIG. 3B is a corresponding cross-sectional view of the semiconductor device 200, in accordance with various embodiments.

As shown in FIG. 3B, a plurality of openings 232 can be formed in the semiconductor device 200 at operation 104. The openings may also be referred to, herein, as device regions. For example, the device regions can contain one or more semiconductor devices such as stacked vertical transistors. In various embodiments, the openings 232 may be formed by one or more etching processes performed on the various dielectric and conductive materials. The etching or other process can be directional (e.g., vertically directional) such that the opening is orthogonal to a plane defined by a surface of at least one of the layers formed at operation 102. For example, a patternable layer may be first formed over the semiconductor device 200. The patternable layer may be etched to form a number of patterns, and those patterns formed in the first patternable layer are then transferred to the semiconductor device 200 through at least one etching process. For example, one or more etching processes can be selected for one or more layers of the semiconductor device 200, and sequenced to form the openings 232. The etching process may be anisotropic and/or isotropic. In some embodiments the openings 232 can be formed by another operation. For example, micro drilling, laser ablation, and other operations can form the openings 232 instead of or in addition to the one or more etching processes. The etching can be a selected shape. For example, a pattern can be generally circular to result in generally cylindrical openings 232.

In some embodiments, the openings 232 or a portion thereof can be lined or seeded. For example, a selective liner or seed can adhere to the fourth layer 210 or tenth layer 222 (e.g., a gate electrode layer). A high-k dielectric 244 can be grown thereupon by atomic layer deposition (ALD) over the seed layer. A high-k dielectric 244 can be adhered to the conductive layers by one or more operations. For example, a portion of the fourth layer 210 or tenth layer 222 can be horizontally etched, and the high K dielectric can be adhered to a resultant horizontal recess.

With continued reference to FIG. 3B, a plurality of layers can be disposed within each of the plurality of openings 232 corresponding to operation 106. For example, a first opening layer 234 can be formed upon the substrate 202. The first opening layer 234 can be or include a dielectric or semiconductor such as silicon-germanium which can be etched or otherwise removed selectively (e.g., may be a sacrificial segment such as a sacrificial semiconductor segment), relative to adjoining materials, or can be selected according to a dielectric property such a dielectric constant which may impact a capacitance of the operation of one or more transistors in proximity to the first opening layer 234. A second opening layer 236 can be formed over the first opening layer 234. For example, the second opening layer 236 can be a doped semiconductor layer, such as a p-type semiconductor which can form a first transistor body (e.g., a first semiconductor segment). A third opening layer 238 can be formed over the second opening layer 236. The third opening layer 238 can be selected according to a property such as an etch-ability or a dielectric property which can impact the performance of the adjoining layer. For example, the third opening layer 238 can be a same dielectric material as the first opening layer 234. The third opening layer 238 can be disposed between the second opening layer 236 and a fourth opening layer 240, which may include one or more components of a transistor. With further reference to the fourth opening layer 240, another semiconductor segment which can form a second transistor (e.g., stacked over the first transistor, comprising the second opening layer 236). An opening cap dielectric layer 242 can cap the opening 232, such as by an additive process and a subsequent planarization.

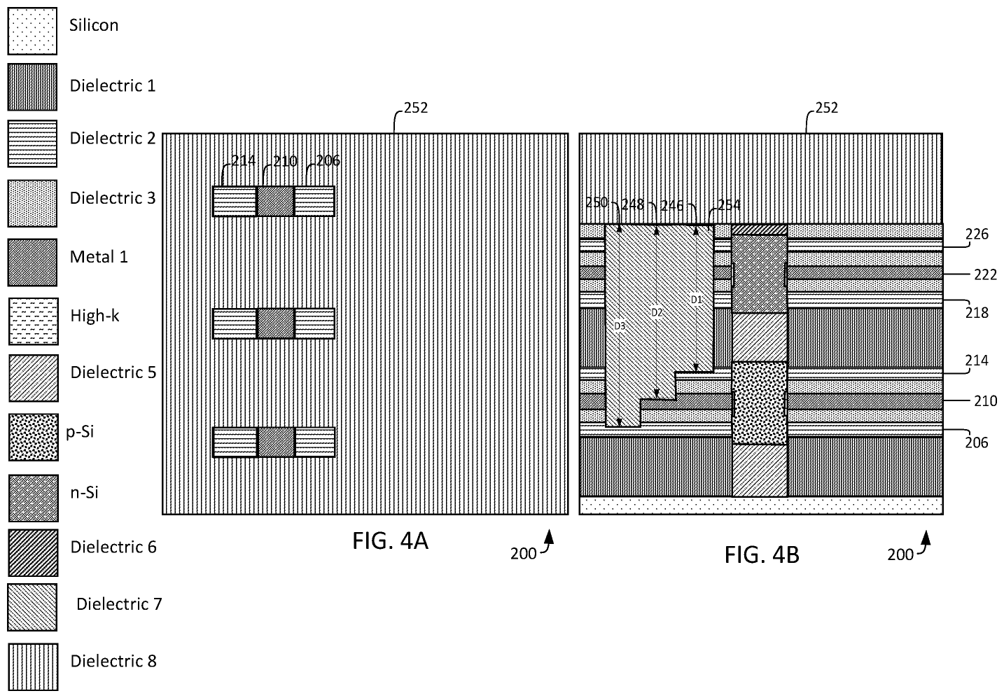

Corresponding to operation 108 and 110 of FIG. 1, FIG. 4A is a top view of the semiconductor device 200 in which a stair-step feature is formed alongside the opening 232, and an additional dielectric layer 252 (e.g., a hard mask) is formed over the semiconductor device 200, respectively. FIG. 2B is a corresponding cross-sectional view of the semiconductor device 200, in accordance with various embodiments.

As shown in FIG. 4B, a side view of one or more of the openings 232 depicted in FIG. 3B is provided. The semiconductor device 200 can be etched (e.g., by a selective directional process) to form a stair-step region at operation 108 of FIG. 1. The stair-step region can include a first depth 246, a second depth 248, and a third depth 250. The various depths can correspond to the depth of selected layers of the semiconductor device 200. For example, the etching can reach a surface or another portion of a conductive layer (e.g., a metal layer), and a layer configured for replacement with a conductive layer. For example, the first depth 246 can be to a surface of a sixth layer 214 of the semiconductor device 200. The second depth 248 can be to a surface of a fourth layer 210 of the semiconductor device 200. The third depth 250 can be to a surface of the second layer 206 of the semiconductor device 200. The etched area can be filled with a dielectric fill 254.

In some embodiments, one or more conductive layers can be otherwise joined to one or more conductive surfaces of the semiconductor device 200. For example, the device can be etched from a bottom side, or one or more conductive elements can be connected to a side of the semiconductor device 200 at one or more conductive layers. In some embodiments, another geometry can connect to the conductive layers to the surface of the semiconductor device 200. For example, the various connections can be radially disposed around the opening 232 (e.g., to reduce a footprint of the semiconductor device 200).

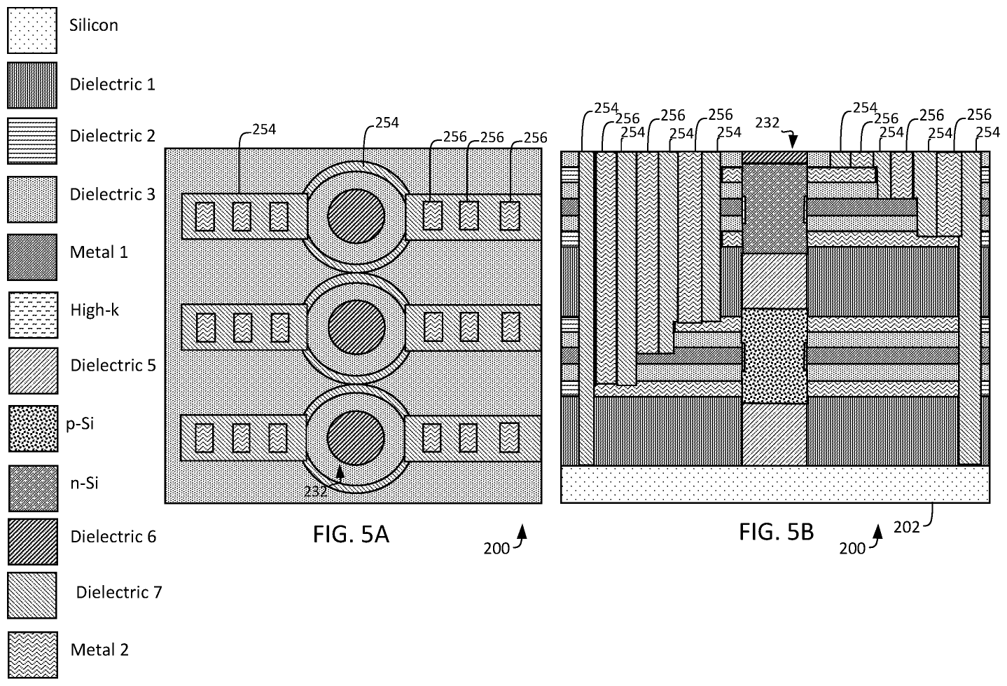

Additional conductive layers can be connected in a similar, same, or different operation. For example, an additional stair-step feature can be formed to a surface (e.g., a surface formed by etching) of the eighth layer 218, the tenth layer 222, and the twelfth layer 226 of the semiconductor device 200. One or more vertical conductive elements can thereafter be included in the stair-step feature to form electrical connections extending between a surface of the semiconductor device 200 and the various layers thereof. The various electrical connections can be insulated therebetween. For example, a dielectric can fill the stair-step feature to insulate later added vertical conductive elements (as will be discussed with further detail with regards to FIGS. 5A and 5B). Additional dielectrics can be formed over the various conductive (e.g., metal) layers. For example, additional dielectric layers can be disposed between the dielectric of the stair-step feature.

With continued reference to FIG. 4B, one or more additional dielectric layers 252 can be formed over the semiconductor device 200. For example, the one or more additional dielectric layers 252 can be a hard mask layer which can protect a surface of the semiconductor device 200 during one or more operations. For example, the additional dielectric layer 252 can be formed prior to operation 110, and removed thereafter, or the additional dielectric layer 252 can protect a surface of the semiconductor device 200 during one or more sub-operations of operation 112. For example, the additional dielectric layer 252 can protect the surface of the semiconductor device 200 during the removal of dielectric layers (e.g., of a same or similar dielectric material) for replacement with a horizontal conductive element.

Corresponding to operation 112 of FIG. 1, FIG. 5A is a top view of the semiconductor device 200 in which a plurality electrical connections are formed between a surface of the semiconductor device 200 and a gate, source, or drain of one or more transistors. FIG. 5B is a corresponding cross-sectional view of the semiconductor device 200, in accordance with various embodiments.

As shown in FIG. 5B, the dielectric fill 254 of the stair step fill is etched to form voids. A conductive material 256 (e.g., a metal) can be inserted into the voids. For example, a pouring or deposition (e.g., ALD, or chemical-vapor deposition CVD) process can fill the voids with the conductive material 256 (being or including copper, aluminum, or another metal or non-metal material). In some embodiments, the conductive material 256 can be formed along one or more layers of the semiconductor device 200. For example, a layer can be horizontally etched to remove a dielectric material, and thereafter filled with the conductive material 256, such as the same conductive material 256 to be disposed between the dielectric fill 254 (e.g., to form a continuous deposition of the conductive material 256 from the surface of the semiconductor device 200 to a surface of the one or more semiconductor layers disposed within the openings 232). Thus, the conductive material 256 can form conductive structure having lateral portions and electrically connected vertical portions.

In some embodiments, the dielectric fill 254 can extend to the substrate 202. The dielectric fill 254 can thereby protect one or more portions of the semiconductor device 200 (e.g., while forming the conductive material 256). The dielectric fill 254 can otherwise surround the openings 232. For example, a generally circular pattern can join one or more stair-step patterns adjoining one or more openings 232 to laterally surround the openings 232 in a dielectric shell (e.g., as depicted in FIG. 5A). The dielectric fill 254 can be deposited during various operations. For example, the dielectric fill 254 can be inserted during operation 110 and can extend to the substrate 202 and surround the openings 232. In some embodiments, a first portion the dielectric fill 254 can be formed (e.g., deposited) during operation 110, and a second portion can be formed during operation 112.

An upper surface of the semiconductor device 200 can be planarized to remove any excess conductive material 256, dielectric fill 254, or additional layers of the semiconductor device 200. For example, the additional dielectric layer 252 can be removed from the semiconductor device 200 by a grinding or polishing process such as chemical mechanical polishing/grinding (CMP/G) to plane an upper surface of the semiconductor device 200.

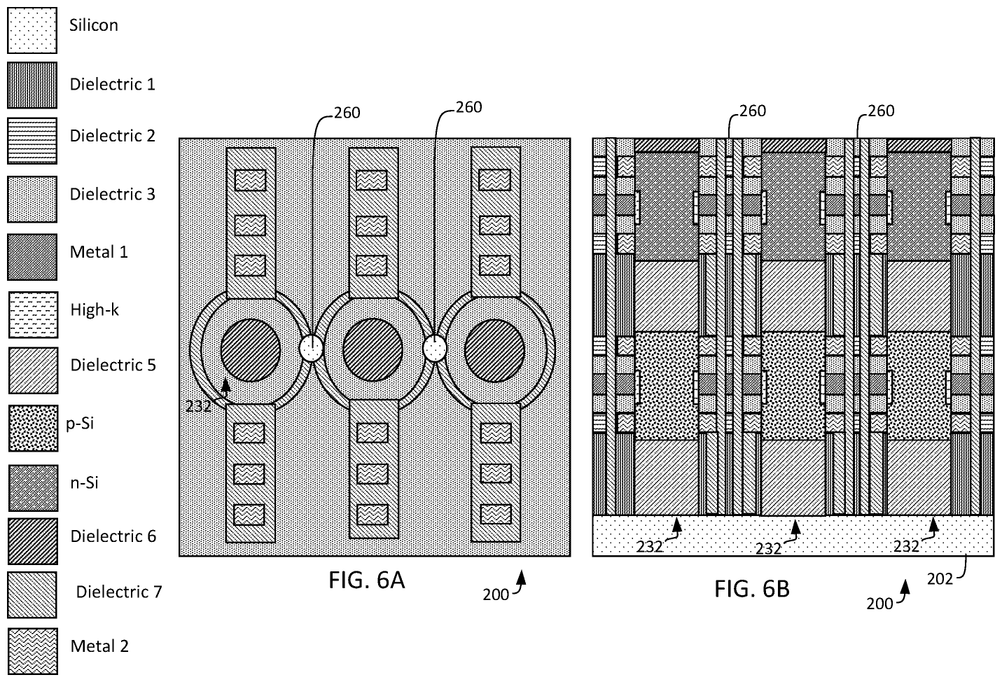

Corresponding to operation 114 of FIG. 1, FIG. 6A is a top view of the semiconductor device 200 in which one or more trenches are formed between a surface of the semiconductor device 200 and the substrate 202. FIG. 6B is a corresponding cross-sectional view of the semiconductor device 200, in accordance with various embodiments.

FIG. 6B returns to the side view of a plurality of openings 232 (e.g., the view of FIG. 3B) to better illustrate the one or more trench holes 260 formed (e.g., photoresist-patterned and stripped) between the openings 232. The trench holes 260 can be formed by a directional etching process, micro-drilling, a selective etch of a portion of the dielectric fill 254, or other methods. The trench hole 260 can extend to or through the substrate 202. The trench holes 260 can be disposed at one or more points around the periphery of the dielectric fill 254. In some embodiments, the trench holes 260 can be formed at a junction of two dielectric fill 254 rings surrounding respective openings 232. In some embodiments, the trench holes 260 can be formed at alternating linear junctions, such that about one trench hole 260 is formed for every two openings 232. In some embodiments, a plurality of trench holes 260 can be formed around the periphery of each opening 232 (e.g., to increase a number of trench holes 260 adjacent to each opening 232).

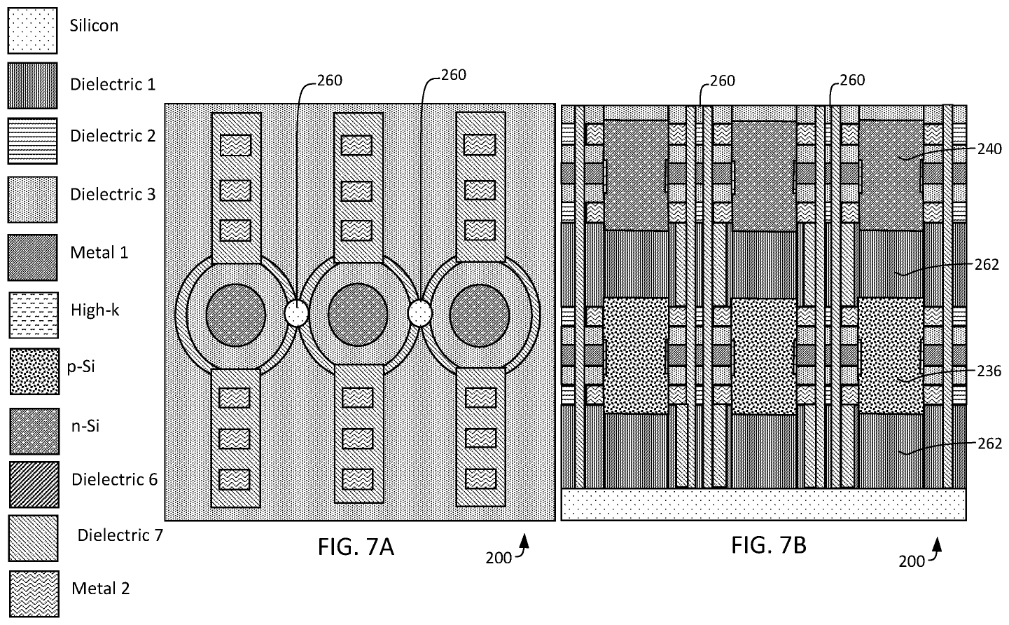

Corresponding to operation 116 of FIG. 1, FIG. 7A is a top view of the semiconductor device 200 in which one or more layers of the semiconductor device 200 are etched to create air gaps 262. FIG. 7B is a corresponding cross-sectional view of the semiconductor device 200, in accordance with various embodiments.

As shown in FIG. 7B, an etchant can be placed (e.g., via the one or more trench holes 260 associated with each opening 232). The etchant can selectively etch one or more layers of the semiconductor device 200. For example, the etchant can selectively etch one or more of the first opening layer 234 of the semiconductor device 200, the third opening layer 238 of the semiconductor device 200, or the opening cap dielectric layer 242. In some embodiments, the etched layers can be or include silicon-germanium. The etching (e.g., wet etching) of the various opening layers can form air gaps 262 in the semiconductor device 200. For example, the air gaps 262, can be formed between semiconductor layers/segments disposed within the openings 232. The air gaps 262 can result in lower capacitance of various conductive elements, or can be filled with a dielectric or other material. For example, each of a second opening layer 236 and a fourth opening layer 240 can be or include a semiconductor (e.g., a doped semiconductor). The semiconductors can form a transistor. For example, the connective structures can form gate, drain, and source electrodes, connected to the body of the transistor (e.g., the semiconductor segments). The body of the transistor can be separated from additional elements of the semiconductor device 200 by the one or more air gaps 262.

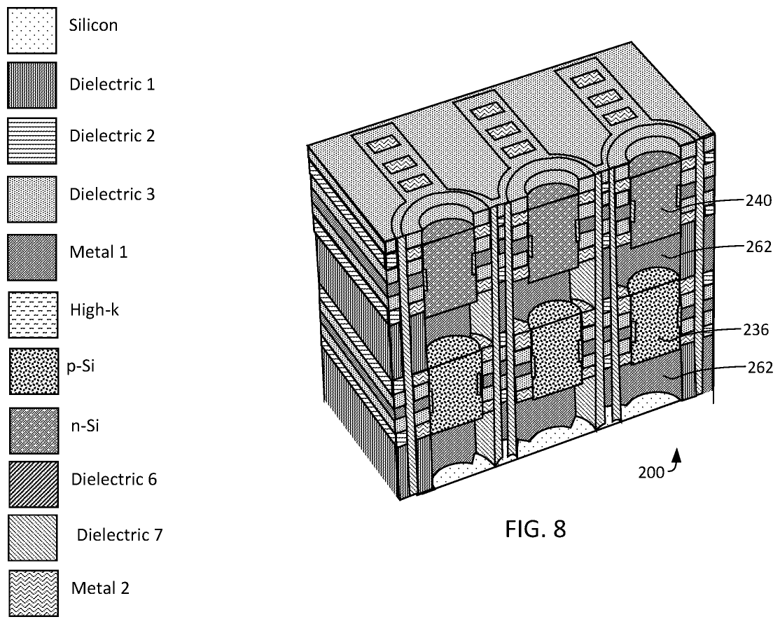

Referring now to FIG. 8, an isometric cross sectional view of the semiconductor device 200 of FIGS. 7A and 7B is provided to better illustrate the air gaps 262 disposed within the openings 232. The connections to the side wall of the opening 232 (e.g., by a plurality of interconnect structures including conductive layers or dielectric layers insulating said conductive layers). Various air or dielectric layers may be referred to as insulating layers herein. For example, the connections to the side wall of the opening 232 can comprise mechanical and electrical connections thereto. For example, the mechanical connection of the sidewalls can provide mechanical support such that the air gaps 262 formed at least above and below the semiconductor segments can be formed.

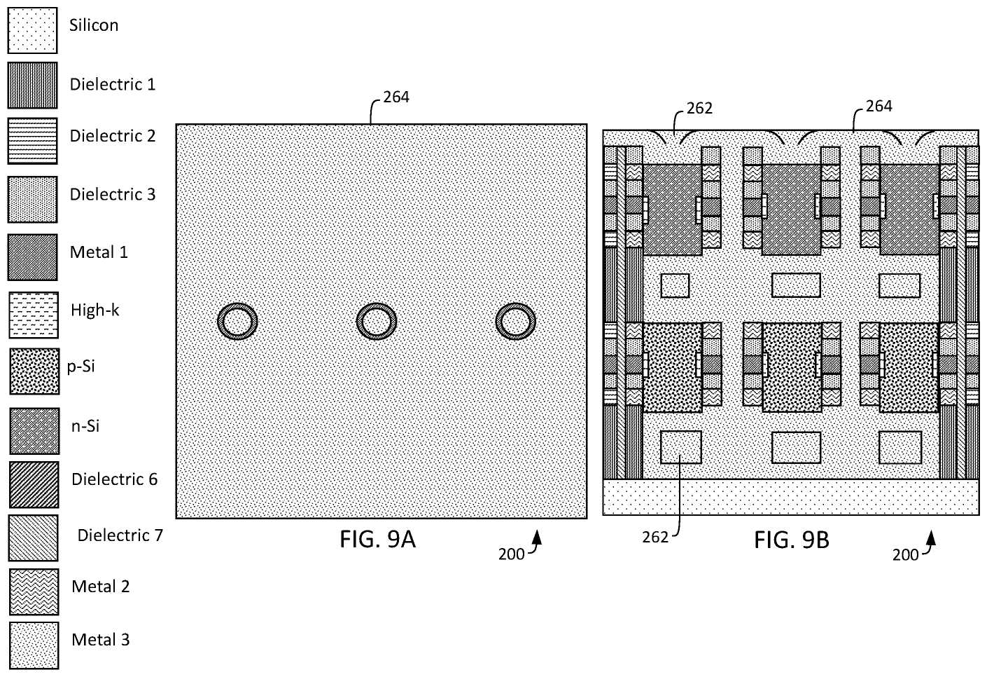

Corresponding to operation 118 of FIG. 1, FIG. 9A is a top view of the semiconductor device 200 in which one or more metal layers 264 are formed over the air gaps 262 or surface of the semiconductor device 200. FIG. 9B is a corresponding cross-sectional view of the semiconductor device 200, in accordance with various embodiments.

As shown in FIG. 9B, a metal layer 264 is formed over one or more surfaces of the semiconductor device 200. For example, the metal layer 264 can be formed by a deposition process such as ALD. In some embodiments, the metal layer 264 can be formed by another deposition process such as a CVD process. In some embodiments, the metal layer 264 can be selectively deposited upon the one or more semiconductor devices 200. For example, the metal layer 264 can be selectively deposited on the (e.g., silicon) substrate 202, and the (e.g., silicon) semiconductor opening layers (e.g., semiconductor segments). The metal layer 264 can be or include various metals such as titanium, tungsten, oxides thereof, or the like). The metal layer 264 can fill one or more voids of the semiconductor device 200, or one or more air gaps 262 can remain following the formation of the metal layer 264.

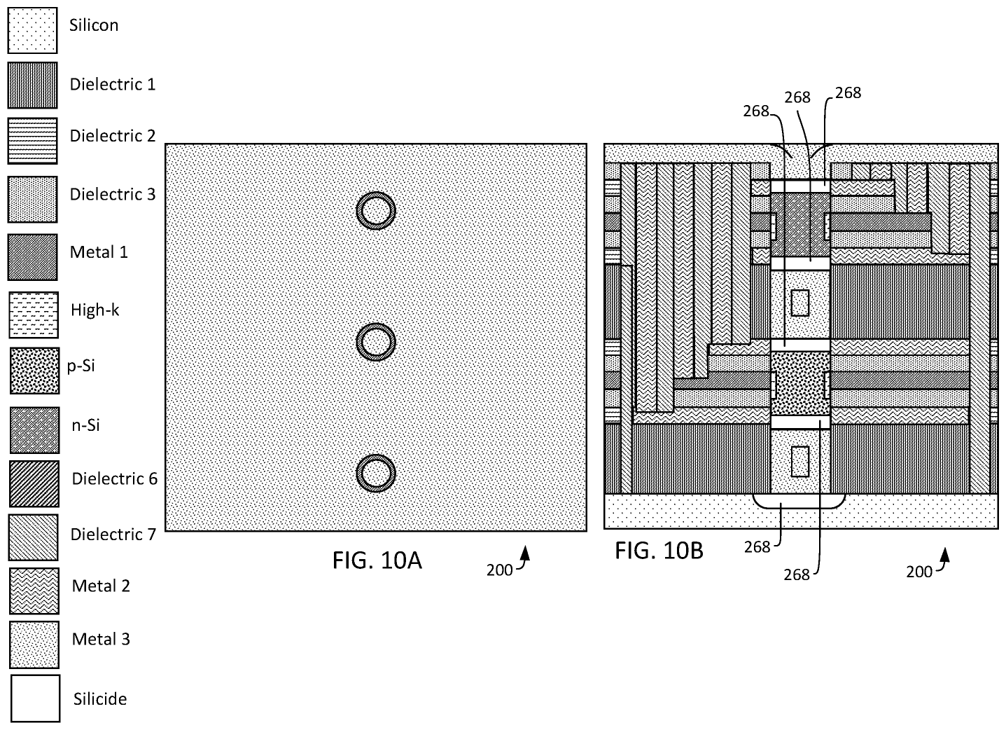

Corresponding to operation 120 of FIG. 1, FIG. 10A is a top view of the semiconductor device 200 in which one or more unreacted metal layers 264 are reacted to form one or more silicides. FIG. 10B is a corresponding cross-sectional view of the semiconductor device 200, in accordance with various embodiments.

As shown in FIG. 10B, a silicide layer 268 is formed over one or more portions of the semiconductor device 200. For example, the silicide layer 268 can be formed along one or more junctions of the metal layer 264 and one or more silicon portions (e.g., the various semiconductor layers and substrate 202 referred to herein). The silicide layer 268 can be formed by reacting (e.g., annealing) the metal layer 264 with the silicon such as by the application of heat. For example, a silicide can be formed at a titanium-silicon junction (e.g., titanium di-silicide), or a tungsten-silicon junction (e.g., tungsten di-silicide). Indeed, various silicides can be formed according to an application of various temperatures to various metal layers 264. The silicides may connect (e.g., electrically, mechanical, and thermally), with various conductive elements (e.g., the interconnect structures). For example, silicide layers 268 may be formed at the junction of the semiconductor segments to one or more electrodes such as a gate electrode (e.g., the fourth layer 210 of the semiconductor device 200), a drain electrode, or source electrode (e.g., the second layer 206 of the semiconductor device 200 or the sixth layer 214 of the semiconductor device 200). The formation of the silicide layers 268 can be controlled such as according to a time and temperature to form the connection (e.g., a low resistance connection). In some embodiments, additional silicide layers 268 can be formed upon additional junctions of additional semiconductor segments. For example, silicide layers 268 can be formed upon semiconductor segments which are stacked with a height of three, four, or five semiconductor segments.

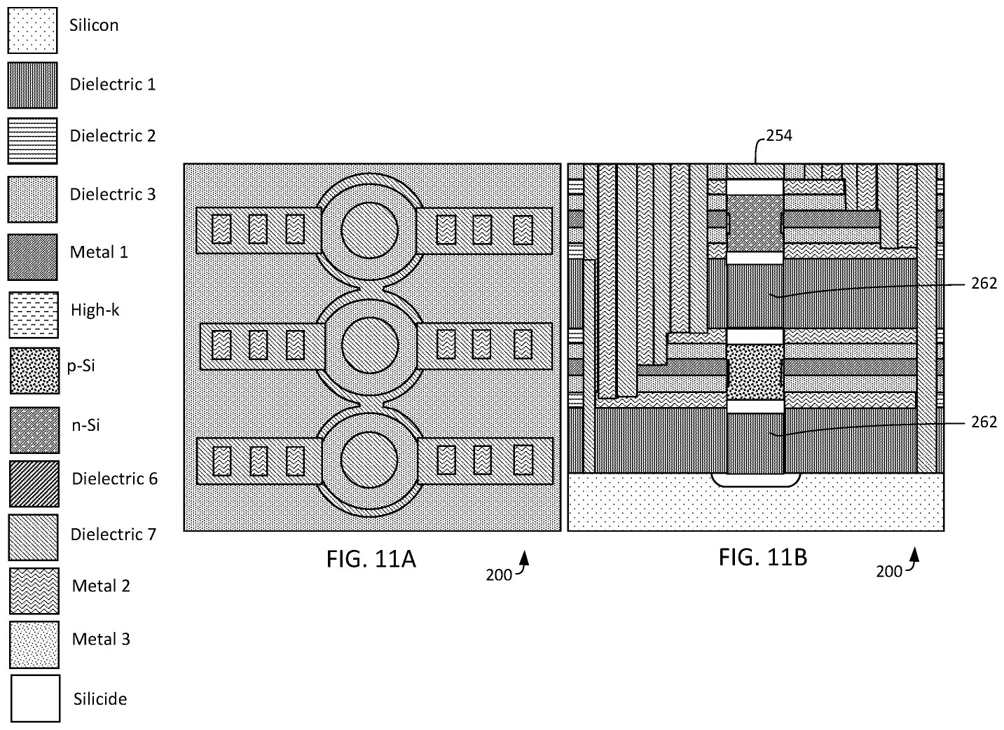

Corresponding to operation 122 of FIG. 1, FIG. 11A is a top view of the semiconductor device 200 in which one or more unreacted metal layers 264 are removed to restore air gaps 262. FIG. 11B is a corresponding cross-sectional view of the semiconductor device 200, in accordance with various embodiments.

As shown in FIG. 11B, an etching process (e.g., a wet etching process) can remove the unreacted metal layers 264. For example, a selective etchant can be used which is reactive with the unreacted metal layers 264 and unreactive or less reactive with the silicide layers 268 formed along the junctions of the silicon portions of the semiconductor device 200. The removal of the unreacted metal layers 264 can electrically disconnect the second opening layer 236 of the semiconductor device 200, and a fourth opening layer 240 of the semiconductor device 200. For example, each of the opening layers can form the body of a transistor (e.g., a semiconductor segment) wherein the gate electrode interconnect structure of the transistor is or is connected to the fourth layer 210 of the semiconductor device 200 or the tenth layer 222 of the semiconductor device 200. The source and drain electrode interconnect structures of the respective transistors can be or include the second layer 206, sixth layer 214, eighth layer 218, or twelfth layer 226 of the semiconductor device 200.

The etching of the unreacted metal layers 264 can result in one or more air gaps 262. The air gaps 262 can decrease a capacitance between various conductive elements of the transistors described above, relative to semiconductor devices 200 including a dielectric with a greater dielectric constant. One or more air gaps 262 can be filled with a dielectric fill 254. For example, an upper portion of the semiconductor device 200 can be filled with a dielectric fill 254. The dielectric fill 254 can protect a surface of the semiconductor device 200 (e.g., to allow for the fabrication of additional stacked transistors, or interconnections to the various conductive elements, such as the conductive elements formed in the stair-step element).

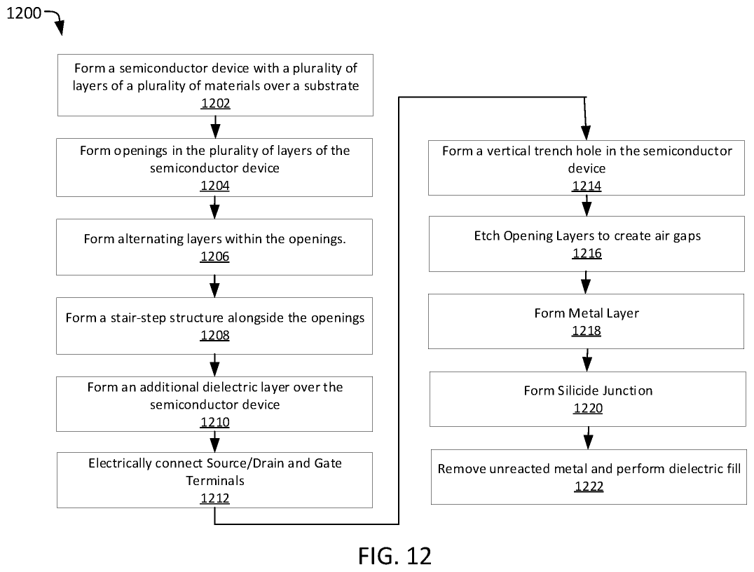

FIG. 12 is another flowchart of another example method 1200 for forming a semiconductor device 200 (e.g., a transistor) having a generally vertical stack structure. For example, the one or more transistors may be vertical stacked transistors with a silicided portion electrically connecting one or more electrodes to the body of at least one vertically stacked transistor. It is noted that the method 1200 is merely an example, and is not intended to limit the present disclosure. Accordingly, it is understood that additional operations may be provided before, during, and after the method 1200 of FIG. 12, and that some other operations may only be briefly described herein.

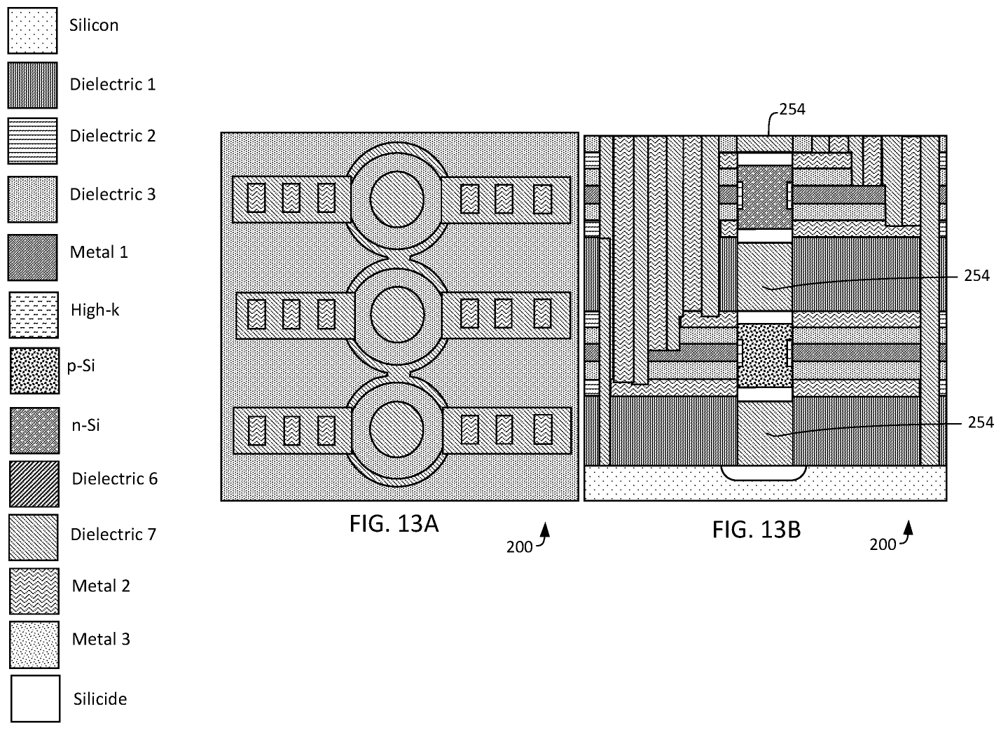

In various embodiments, operations of the method 1200 may be associated with a top views and cross-sectional views of an example semiconductor device 200 at various fabrication stages as shown in FIGS. 13A and 13B, respectively, which will be discussed in further detail below. It should be understood that the semiconductor device 200, shown in FIGS. 13A and 13B, may include a number of other devices such as inductors, fuses, capacitors, coils, etc., while remaining within the scope of the present disclosure.

In brief overview, the method 1200 starts with operation 1202 of forming a semiconductor device 200 comprising a plurality of materials formed over a substrate. The method 1200 continues to operation 1204 of forming a number of openings in the semiconductor device. In various embodiments, the openings can be generally cylindrical. The method 1200 proceeds to operation 1206 of forming a plurality of layers disposed within the openings of the semiconductor device. The method 1200 proceeds to operation 1208 of forming a connection structure alongside the openings. In some embodiments, the connection structure can be or include a stair-step structure. The method 1200 proceeds to operation 1210 of forming an additional dielectric layer over the semiconductor device. The method 1200 proceeds to operation 1212 of electrically connecting the source/drain and gate terminals. The method 1200 proceeds to operation 1214 of forming vertical trench holes in the semiconductor device. The method 1200 proceeds to operation 1216 whereby one or more opening layers are etched to create air gaps. The method 1200 proceeds to operation 1218 of growing a metal layer over the semiconductor device. The method 1200 proceeds to operation 1220 of forming a silicide junction. The method 1200 proceeds to operation 1222 of removing unreacted metal and completing a dielectric fill.

Various operations depicted in FIG. 12 may be similar to other operations depicted in this disclosure. For example, in various embodiments, the operations 1202, 1204, 1206, 1208, 1210, 1212, 1214, 1216, 1218, and 1220 may be performed in a fashion as has previously been discussed with regards to operations 102, 104, 106, 108, 110, 112, 114, 116, 118, and 120 as depicted in FIG. 1.

Corresponding to operation 1222 of FIG. 12, FIG. 13A is a top view of the semiconductor device 200 in which one or more unreacted metal layers 264 are removed and filled with a dielectric material. FIG. 13B is a corresponding cross-sectional view of the semiconductor device 200, in accordance with various embodiments.

As shown in FIG. 13B, the unreacted metal layer 264 can be removed from the semiconductor device 200. For example, an etching process (e.g., a wet etching process) can remove the unreacted metal layers 264. For example, a selective etchant can be used which is reactive with the unreacted metal layers 264 and unreactive or less reactive with the silicide layers 268 formed along the junctions of the silicon portions of the semiconductor device 200. For example, the removal of the unreacted metal layers 264 can result in the transistors described with reference to FIGS. 11A and 11B. The voids remaining from the removal of the unreacted metal layers 264 can be filled with a dielectric fill 254 such that a layer of the dielectric fill 254 separates the semiconductor segments, rather than an air gap.

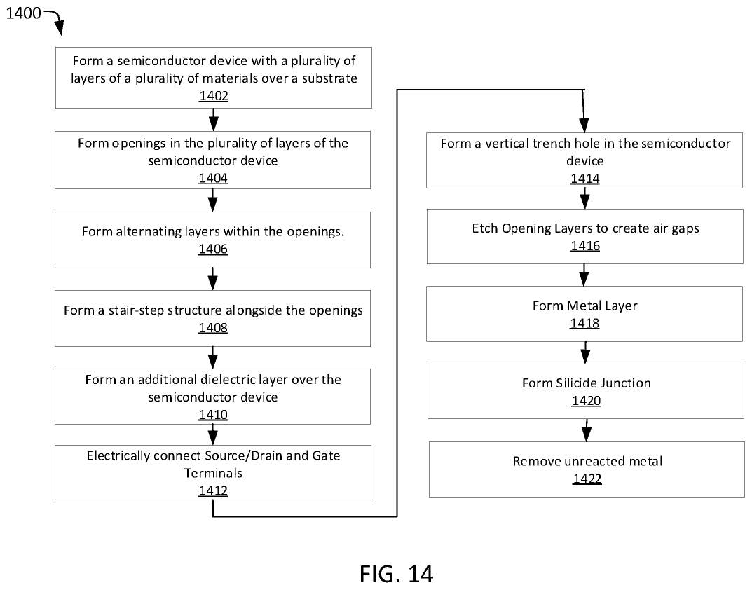

FIG. 14 is another flowchart of another example method 1400 for forming a semiconductor device 200 (e.g., a transistor) having a generally vertical stack structure. For example, the one or more transistors may be vertical stacked transistors with a silicided portion electrically connecting one or more electrodes to the body of at least one vertically stacked transistor. It is noted that the method 1400 is merely an example, and is not intended to limit the present disclosure. Accordingly, it is understood that additional operations may be provided before, during, and after the method 1400 of FIG. 14, and that some other operations may only be briefly described herein.

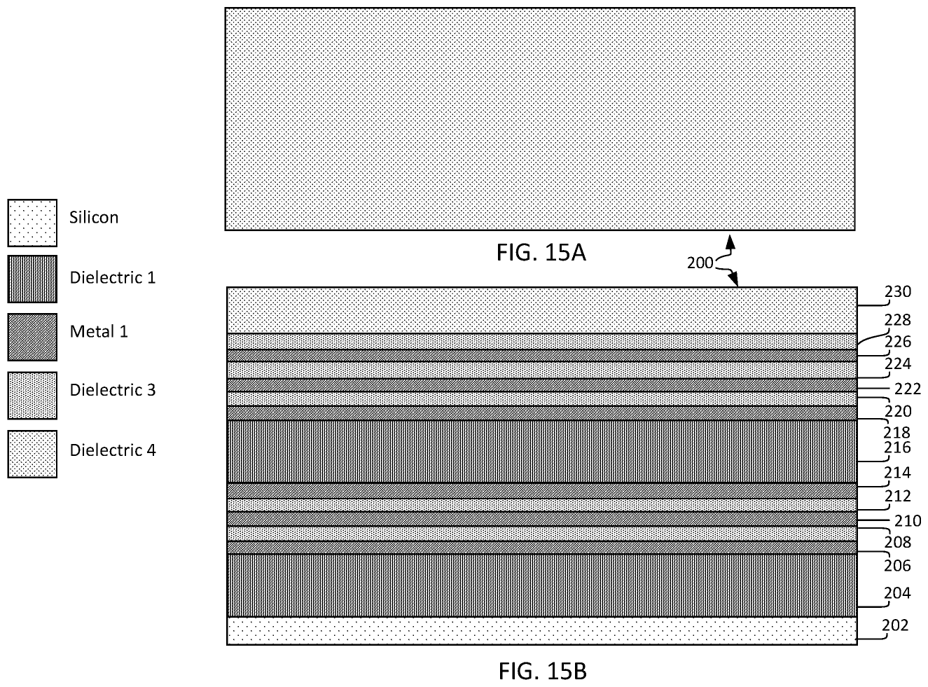

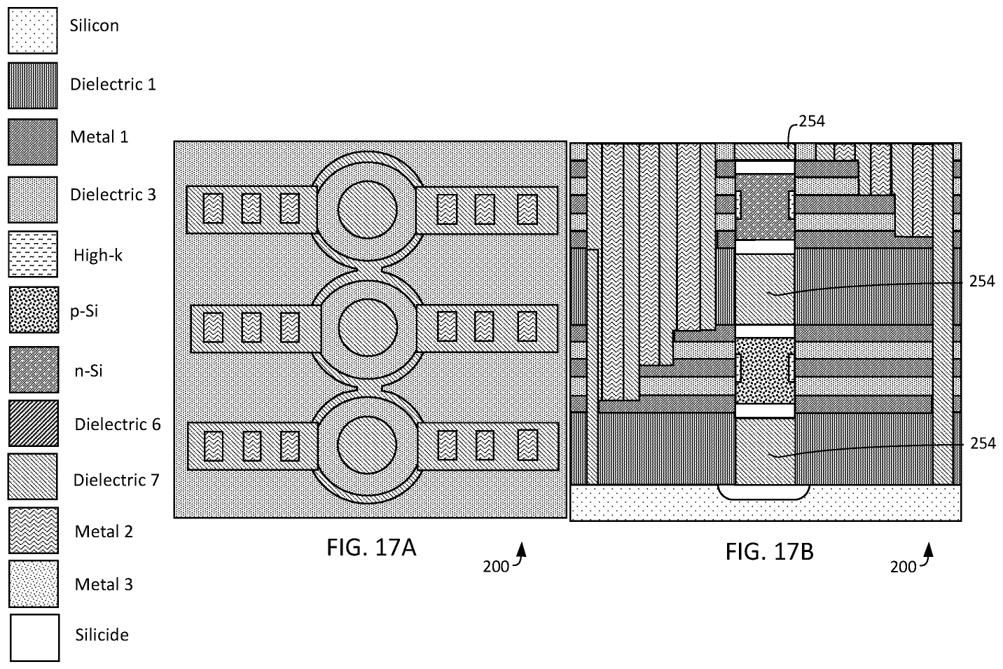

In various embodiments, operations of the method 1400 may be associated with top views and cross-sectional views of an example semiconductor device 200 at various fabrication stages as shown in FIGS. 15A to 17A and FIGS. 15B to 17B, respectively, which will be discussed in further detail below. It should be understood that the semiconductor device 200, shown in FIGS. FIGS. 15A to 17A and FIGS. 15B to 17B may include a number of other devices such as inductors, fuses, capacitors, coils, etc., while remaining within the scope of the present disclosure.

In brief overview, the method 1400 starts with operation 1402 of forming a semiconductor device comprising a plurality of materials formed over a substrate. The method 1400 continues to operation 1404 of forming a number of openings in the semiconductor device. In various embodiments, the openings can be generally cylindrical. The method 1400 proceeds to operation 1406 of forming a plurality of layers disposed within the openings of the semiconductor device. The method 1400 proceeds to operation 1408 of forming a connection structure alongside the openings. In some embodiments, the connection structure can be or include a stair-step structure. The method 1400 proceeds to operation 1410 of forming an additional dielectric layer over the semiconductor device. The method 1400 proceeds to operation 1412 of electrically connecting the source/drain and gate terminals. The method 1400 proceeds to operation 1414 of forming vertical trench in the semiconductor device. The method 1400 proceeds to operation 1416 whereby one or more opening layers are etched to create air gaps. The method 1400 proceeds to operation 1418 of growing a metal layer over the semiconductor device. The method 1400 proceeds to operation 1420 of forming a silicide junction. The method 1400 proceeds to operation 1422 of removing unreacted metal.

Corresponding to operation 1402 of FIG. 14, FIG. 15A is a top view of the semiconductor device 200 in which a plurality of layers are formed of a plurality of materials (e.g., conductive and dielectric materials). FIG. 15B is a corresponding cross-sectional view of the semiconductor device 200, in accordance with various embodiments.

As shown in FIG. 15B, a plurality of layers (e.g., blanket layers) are formed over the substrate 202. A portion of the plurality of layers may be similar to the layers depicted and described with reference to FIGS. 2A and 2B. Some layers can be substituted, omitted, or added. For example, some dielectric layers of the semiconductor device 200 can be formed from a conductive material. For example, the second layer 206, sixth layer 214, eighth layer 218, and twelfth layer 226 of the semiconductor device 200 (e.g., the electrodes for the source/drain for each of the transistors to be formed from the semiconductor device 200) can be formed from a conductive material. The conductive material can be a same metal layer as the fourth layer 210 and the tenth layer 222 of the semiconductor device 200 (e.g., the gate electrodes).

Various operations depicted in FIG. 14 may be similar to other operations depicted in this disclosure. For example, in various embodiments, the operations 1404, 1406, 1408, 1410, 1412, 1414, 1416, 1418, and 1420 may be performed in a fashion as has previously been discussed with regards to operations 104, 106, 108, 110, 112, 114, 116, 118, and 120 as depicted in FIG. 1. The operations can be adjusted based on the layers formed in operation 1402. For example, at operation 1412, the vertical portion of the interconnect structure can be joined to the conductive structure deposited in the semiconductor device 200 at operation 1402, and the sub-operation of horizontally etching the dielectric layer can be omitted.

Referring now to FIGS. 15A and 15B, a semiconductor device 200 is depicted. The semiconductor device 200 can be formed according to the method 1400 of FIG. 14, wherein operation 1422 can be or include the sub-operations described with reference to FIG. 11B (e.g., operation 122). For example, the semiconductor device 200 can include one or more transistors separated by air gaps 262. A dielectric fill 254 can be formed upon a surface of the semiconductor device 200, such as by a deposition and planarization process.

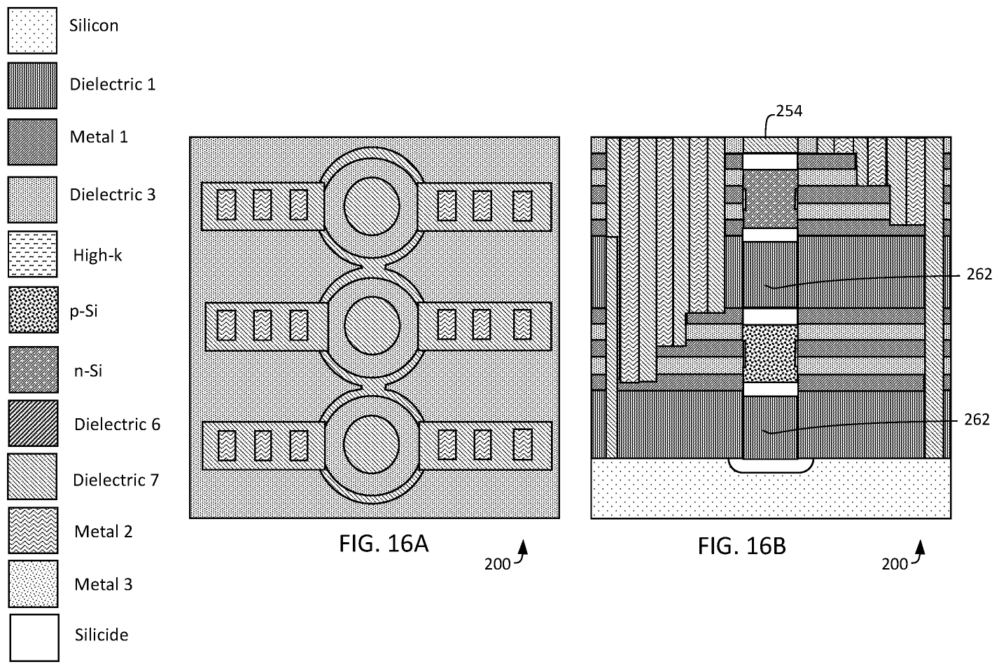

Referring now to FIGS. 16A, and 16B, another semiconductor device 200 is depicted. The semiconductor device 200 can be formed according to the method 1400 of FIG. 14, wherein operation 1422 can be or include the sub-operations described with reference to FIG. 13B (e.g., operation 1222). For example, the semiconductor device 200 can include one or more transistors separated by a dielectric fill 254. The dielectric fill 254 can be formed between the transistors to fill voids revealed by the removal of the metal layer 264, and upon a surface of the semiconductor device 200, such as by a deposition and planarization process.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A transistor structure comprising:
a stack of layers including:
a source contact layer,
a gate contact layer with a first insulation layer between the gate contact layer and the source contact layer, and
a drain contact layer with a second insulation layer between the gate contact layer and the drain contact layer;
a device region orthogonal to a plane defined by a surface of at least one of the layers in the stack of layers, the device region comprising a source and drain separated by a channel region; and
silicide regions at ends of the device region proximal to the source and drain.

2. The transistor structure of claim 1 wherein the gate contact layer at least partially surrounds the channel region with a gate dielectric interposed between the gate contact layer and the channel region.

3. The transistor structure of claim 1 wherein the gate contact layer forms a ring around the channel region with a gate dielectric interposed between the gate contact layer and the channel region.

4. The transistor structure of claim 1 wherein each one of the source, the drain, and the channel are at least partially surrounded by one or more dielectric materials.

5. The transistor structure of claim 1, comprising:
a first silicide region at a first end of the device region in electrical contact with the source and a second silicide region at a second end of the device region in electrical contact with the drain.

6. The transistor structure of claim 1, comprising a hollow core extending orthogonally through a central portion of the device region, wherein the hollow core comprises one of air or dielectric material.

7. The transistor structure of claim 1, wherein the source contact layer is in electrical contact with the source via a first silicide region of the silicide regions and the drain contact layer is in electrical contact with the drain via a second silicide region of the silicide regions.

8. The transistor structure of claim 7, wherein the source, the gate and the drain are vertically aligned and orthogonal to the plane.

9. A gate all around (GAA) transistor structure comprising:
a substrate;
a stack of layers upon the substrate, the stack of layers including:
a source contact layer,
a gate contact layer with a first insulation layer between the gate contact layer and the source contact layer, and
a drain contact layer with a second insulation layer between the gate contact layer and the drain contact layer;
a device region orthogonal to a plane defined by a surface of at least one of the layers in the stack of layers, the device region comprising a source and drain separated by a channel region that is at least partially surrounded by a gate dielectric interposed between the gate contact layer and the channel region; and
a first region comprising a silicide formed at a first end of the device region proximal to the source and a second region comprising the silicide formed at a second end of the device region proximal to the drain.

10. The GAA transistor structure of claim 9, wherein the GAA transistor is laterally spaced from an additional GAA transistor structure.

11. The GAA transistor structure of claim 9, wherein the GAA transistor is vertically stacked over an additional GAA transistor structure.

12. The GAA transistor structure of claim 9, wherein the source contact layer is in electrical contact with the source via the first region and the drain contact layer is in electrical contact with the drain via the second region.

13. The GAA transistor structure of claim 9, wherein the source, the gate and the drain are vertically aligned and orthogonal to the plane.

14. The GAA transistor structure of claim 9, comprising a hollow core extending orthogonally through a central portion of the device region, wherein the hollow core comprises at least one of air and a dielectric material.

15. The GAA transistor structure of claim 9, wherein the source contact layer is in electrical contact with the source via a first silicide region of the silicide regions and the drain contact layer is in electrical contact with the drain via a second silicide region of the silicide regions.

16. A method comprising:
forming a stack of layers upon a substrate, the stack of layers including:
a source contact layer;
a gate contact layer with a first insulation layer between the gate contact layer and the source contact layer; and
a drain contact layer with a second insulation layer between the gate contact layer and the drain contact layer;
forming a device region orthogonal to a plane defined by a surface of at least one of the layers in the stack of layers, including:
forming a source of the device region and a drain of the device region;
forming a channel region that is at least partially surrounded by a gate dielectric interposed between the gate contact layer and the channel region to form a gate of the device region, the channel region separating the source from the drain; and
forming a first region comprising silicide at a first end of the device region proximal to the source and a second region comprising the silicide at a second end of the device region proximal to the drain.

17. The method of claim 16, further comprising forming a hollow core extending orthogonally through a central portion of the device region, wherein the hollow core comprises one of air or dielectric material.

18. The method of claim 16, forming, by the gate contact layer, a ring around the channel region with the gate dielectric interposed between the gate contact layer and the channel region.

19. The method of claim 16, wherein the stack of layers further comprises:
an additional source contact layer vertically spaced from the source contact layer;
an additional gate contact layer vertically spaced from the gate contact layer, with an additional first insulation layer between the additional gate contact layer and the additional source contact layer; and
forming an additional channel region vertically spaced from the channel region; and
forming an additional first region comprising silicide vertically spaced from the channel region and the first region.

20. The method of claim 16, further comprising forming an additional device region orthogonal to the plane defined by the surface of at least one of the layers in the stack of layers, laterally spaced from the device region.
